(19) United States
(12) Patent Application Publication
(10) Pub. No.: US 2025/0316575 A1
(43) Pub. Date: Oct. 9, 2025

(54) DIE-FIRST METALLIZATION STRUCTURE AND SUBSTRATE INTERPOSER HYBRID PACKAGE

(71) Applicant: QUALCOMM Incorporated, San Diego, CA (US)

(72) Inventors: Manuel ALDRETE, Encinitas, CA (US); Rajneesh KUMAR, San Diego, CA (US); Sang-Jae LEE, San Diego, CA (US); Zhijie WANG, San Diego, CA (US); Seongho KIM, San Diego, CA (US); Aniket PATIL, San Diego, CA (US)

(21) Appl. No.: 18/625,980

(22) Filed: Apr. 3, 2024

(51) Int. Cl. H01L 23/498; H01L 21/48; H01L 21/56; H01L 23/00

(52) U.S. Cl. CPC H01L 23/49833; H01L 21/4853; H01L 21/4857; H01L 21/565; H01L 23/49816; H01L 23/49822; H01L 23/49838; H01L 24/16; H01L 24/32; H01L 24/73; H01L 2224/16225; H01L 2224/32225; H01L 2224/73253; H01L 2924/1815

(57) ABSTRACT

In an aspect, a die-first metallization structure and substrate interposer hybrid package comprises a substrate interposer having a plurality of electrical connections from electrical contacts on the bottom surface of the substrate interposer to a plurality of vertical conductors mounted on the top surface of the substrate interposer. A semiconductor die is mounted to the top surface of the substrate interposer in a pins-up position and embedded, along with the vertical conductors, in a molding compound. A first metallization structure is disposed above, and electrically connected to, the die and the vertical conductors, and provides an electrical connection to a second set of electrical contacts on a top surface of the first metallization structure. In some aspects, the substrate may be a printed circuit board or similar structure, and the first metallization structure may be a redistribution layer (RDL) or similar structure.

### BACKGROUND OF THE DISCLOSURE

### 1. Field of the Disclosure

This disclosure relates generally to packaging and packaging substrates, and more specifically, but not exclusively, to die-first metallization structure and substrate interposer hybrid packages.

### DESCRIPTION OF THE RELATED ART

FIG. 1 a side cross-sectional view of a conventional package on package (POP) apparatus 100 that is designed to provide electrical connections from a die 102 within the apparatus 100 to a target board to which the apparatus 100 will be attached and also to a top-mounted package (e.g., a memory), both of which are shown here for illustration of relative location only. The conventional apparatus 100 includes a top-side redistribution layer (RDL) interposer 104 and a bottom-side RDL structure 106, which are separated by a body structure 108 that comprises a molding compound and that contains vertical conductors 110 that electrically connect portions of the top-side RDL interposer 104 and the bottom-side RDL structure 106. The vertical conductors 110 are copper posts.

In the example illustrated in FIG. 1, the die 102 is attached to the top-side RDL interposer 104 by a die attach film (DAF) 112, and makes electrical connections to the bottom-side RDL structure 106 through die contacts 114. Contact pads 116 on the top surface of the top-side RDL interposer 104 allow electrical connections to the top-mounted package. Ball contacts 118 on the bottom surface of the bottom-side RDL structure 106 allow electrical connections to the target board.

In the example apparatus 100 shown in FIG. 1, both the top-side RDL interposer 104 and the bottom-side RDL structure 106 comprise multiple polyimide layers 120, embedded within or between which are metallization structures 122 that may be electrically connected through the polyimide layers 120 by vias to metallization structures 122 embedded within or between other polyimide layers 120.

The use of RDL has advantages such as dense signal routing capability and low height along the Z-axis, but also has disadvantages. For example, the top-side RDL interposer 104—a primary heat sink path for the die 102—has poor thermal characteristics due to the polyimide layers 120 and the thin copper contact pads 116. Moreover, the costs and process cycle time is higher for RDL structures compared to alternatives such as prepreg (PPG) and other substrates.

Thus, there is a need for a better approach having none of the disadvantages described above.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an apparatus includes a substrate interposer having a top surface and a bottom surface, the substrate interposer having a plurality of electrical connections from a first set of electrical contacts on the bottom surface of the substrate interposer, through the substrate interposer, to the top surface of the substrate interposer; a plurality of vertical conductors mounted to the top surface of the substrate interposer and extending in a vertical direction, each vertical conductor in the plurality of vertical conductors electrically connected to one electrical connection from the plurality of electrical connections provided by the substrate interposer; a semiconductor die, disposed above the top surface of the substrate interposer, and having a plurality of die contacts disposed on a top surface of the semiconductor die; and a first metallization structure, disposed above the semiconductor die and the plurality of vertical conductors, having at least one electrical connection to each of the plurality of die contacts and to each of the plurality of vertical conductors, and providing an electrical connection to a second set of electrical contacts on a top surface of the first metallization structure, wherein the semiconductor die and the plurality of vertical conductors are contained within a layer, disposed between the top surface of the substrate interposer and a bottom surface of the first metallization structure, comprising a molding compound.

In an aspect, a method for fabricating an apparatus includes providing a substrate interposer having a top surface and a bottom surface, the substrate interposer having a plurality of electrical connections from a first set of electrical contacts on the bottom surface of the substrate interposer, through the substrate interposer, to the top surface of the substrate interposer; forming, on the top surface of the substrate interposer, a plurality of vertical conductors extending in a vertical direction, each vertical conductor in the plurality of vertical conductors electrically connected to at least one electrical connection from the plurality of electrical connections provided by the substrate interposer; mounting a semiconductor die above the top surface of the substrate interposer, the semiconductor die having a plurality of die contacts disposed on a top surface of the semiconductor die; encasing the plurality of vertical conductors and the semiconductor die in a protective layer comprising a molding compound such that the plurality of vertical conductors and the plurality of die contacts remain exposed; and forming a first metallization structure on a top surface of the protective layer, the first metallization structure having at least one electrical connection to each of the plurality of die contacts and to each of the plurality of vertical conductors, and having an electrical connection to a second set of electrical contacts on a top surface of the first metallization structure.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIG. 1 a side cross-sectional view of a conventional package on package (POP) apparatus that is designed to provide electrical connections from a die within the apparatus to a target board to which the apparatus will be attached and also to a top-mounted package.

FIG. 2 a side cross-sectional view of a die-first metallization structure and substrate interposer hybrid package, according to aspects of the disclosure.

FIG. 3A through FIG. 3H illustrate portions of a process for fabricating a die-first metallization structure and substrate interposer hybrid package, according to aspects of the disclosure.

FIG. 4 is a flowchart illustrating steps of an exemplary process for fabricating a die-first metallization structure and substrate interposer hybrid package, according to aspects of the disclosure.

FIG. 5 illustrates an exemplary mobile device in accordance with one or more aspects of the disclosure; and

FIG. 6 illustrates various electronic devices that may be integrated with any of the aforementioned integrated device or semiconductor device in accordance with one or more aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to packaging and packaging substrates. Some aspects more specifically relate to die-first metallization structure and substrate interposer hybrid packages. In some examples, an apparatus comprises a substrate interposer having a plurality of electrical connections from electrical contacts on the bottom surface of the substrate interposer to a plurality of vertical conductors mounted on the top surface of the substrate interposer. A semiconductor die is mounted to the top surface of the substrate interposer in a pins-up position and embedded, along with the vertical conductors, in a molding compound. A first metallization structure is disposed above, and electrically connected to, the die and the vertical conductors, and provides an electrical connection to a second set of electrical contacts on a top surface of the first metallization structure. In some aspects, the substrate may be a printed circuit board or similar structure, and the first metallization structure may be a redistribution layer (RDL) or similar structure.

Particular aspects of the subject matter described in this disclosure can be implemented to realize one or more of the following potential advantages. In some examples, because the substrate interposer may be fabricated separately and provided as a premade item, cost and cycle time to create the apparatus is also reduced. The use of wire bonds or copper pins can reduce pin pitch and further reduce cost compared to the use of copper posts in conventional approaches. Moreover, because the substrate interposer is not RDL, thermal performance is improved. If the metallization structure is an RDL structure, the RDL advantages of better routing and Z-height reduction may still be achieved.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

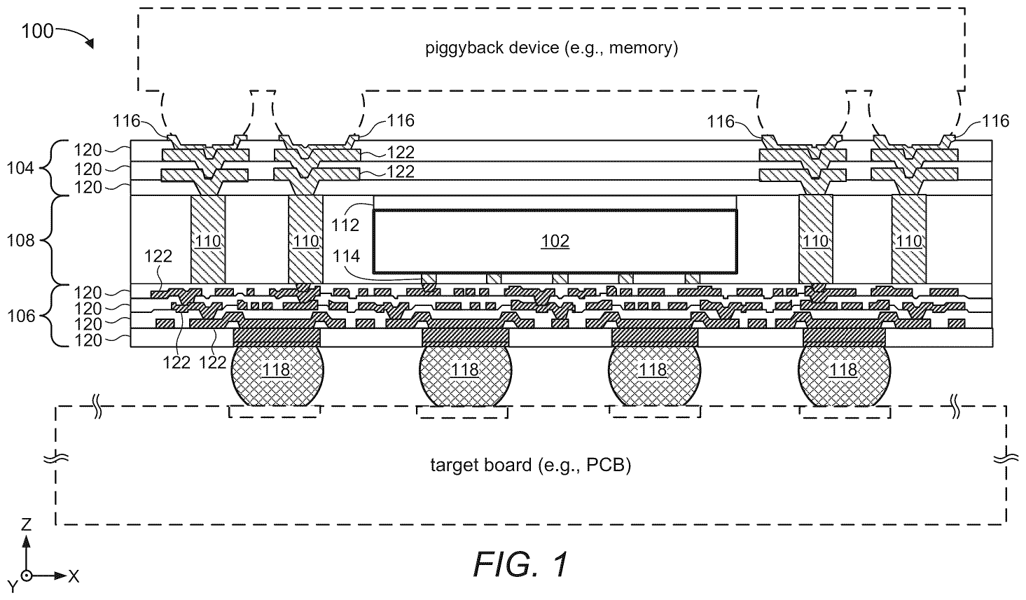

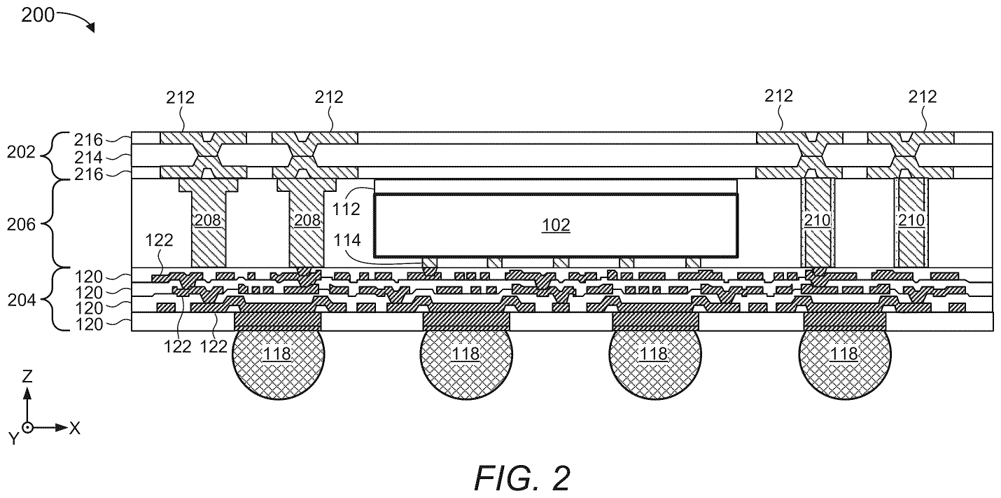

FIG. 2 a side cross-sectional view of an improved apparatus 200, according to aspects of the disclosure. The apparatus 200 comprises a die-first metallization structure and substrate interposer hybrid package. In FIG. 2, the features including the die 102, the DAF 112, the die contacts 114, the contact pads 116, the ball contacts 118, the polyimide layers 120, and the metallization structures 122 are substantially equivalent to the like-numbered features in FIG. 1, and therefore their descriptions will not be repeated here.

In the example illustrated in FIG. 2, the apparatus 200 includes a substrate interposer 202 and a die-first metallization structure 204, which are separated by a body structure 206 that comprises a molding compound and that surrounds the die 102 and that contains vertical conductors that electrically connect portions of substrate interposer 202 and the metallization structure 204. In some aspects, the vertical conductors may be wire bonds 208 or copper pins 210, both of which allow for a thicker die 102 compared to what is allowed by the copper posts used in the conventional apparatus 100. In some aspects, the metallization structure 204 may be an RDL structure.

In some aspects, the substrate interposer 202 may comprise pre-preg with glass fabric (e.g., a “core”) and may have metal (e.g., copper) electrical traces on both its top and bottom surfaces. For example, the substrate interposer 202 may be a copper clad laminate (CCL) core. In some aspects, vias are created by drilling and Cu plating. In some aspects, the substrate interposer 202 has undergone a lithography process to create electrical traces on the top and bottom surfaces.

In the example illustrated in FIG. 2, the substrate interposer 202 comprises a core layer 214 sandwiched between two laminate layers 216, but in other aspects, the substrate interposer 202 may have a greater or fewer number of layers, and may therefore comprise any combination of core and laminate layers, including but not limited to zero or more core layers 214, zero or more laminate layers 216, or combinations thereof. In some aspects, the laminate layers 216 may comprise Ajinomoto build-up film (ABF) and/or prepreg (PPG), and may be fabricated by a printed circuit board (PCB) or substrate process. In the example illustrated in FIG. 2, the top surface of the substrate interposer 202 may be have a solder resist layer or other surface treatment to create metal pads 212, which may comprise solder mask defined (SMD) pads or non-SMD (NSMD) pads.

Unlike the conventional RDL interposer 104 shown in FIG. 1, with polyimide layers 120 having a typical thickness of 3-6 um per layer and metal layers 122 having a typical thickness of 3-9 um per layer for a typical RDL interposer 104 thickness of about 30 μm, the substrate interposer 202 uses core/PPG layers 214 having a thickness of 20-40 um per layer copper traces 212 having a thickness of 10-15 um, for a typical substrate interposer 202 thickness of about 100 um. RDL interposers 104 can have a signal density of about 2 um line thickness and 2 um line spacing, while substrate interposers 202 have >10 um line thickness and line spacing.

In the example illustrated in FIG. 2, the die 102 is attached to the substrate interposer 202 by the DAF 112, and makes electrical connections to the metallization structure 204 through die contacts 114. The metal pads 212 on the top surface of the substrate interposer 202 allow electrical connections to the top-mounted package. Contacts 118 on the bottom surface of the metallization structure 204 allow electrical connections to the target board. In the example illustrated in FIG. 2, the contact 118 are ball contacts, such as ball grid array (BGA) contacts, but posts, pillars, and other types of contacts may be used instead.

Because the substrate interposer 202 may be fabricated separately and provided as a premade item, cost and cycle time to create the apparatus 200 is also reduced. The use of wire bonds 208 or copper pins 210 can reduce pin pitch and further reduce cost compared to the use of copper posts 110 in apparatus 100. Moreover, because the substrate interposer 202 is not RDL, thermal performance is improved. If the metallization structure 204 is an RDL structure, the RDL advantages of better routing and Z-height reduction may still be achieved.

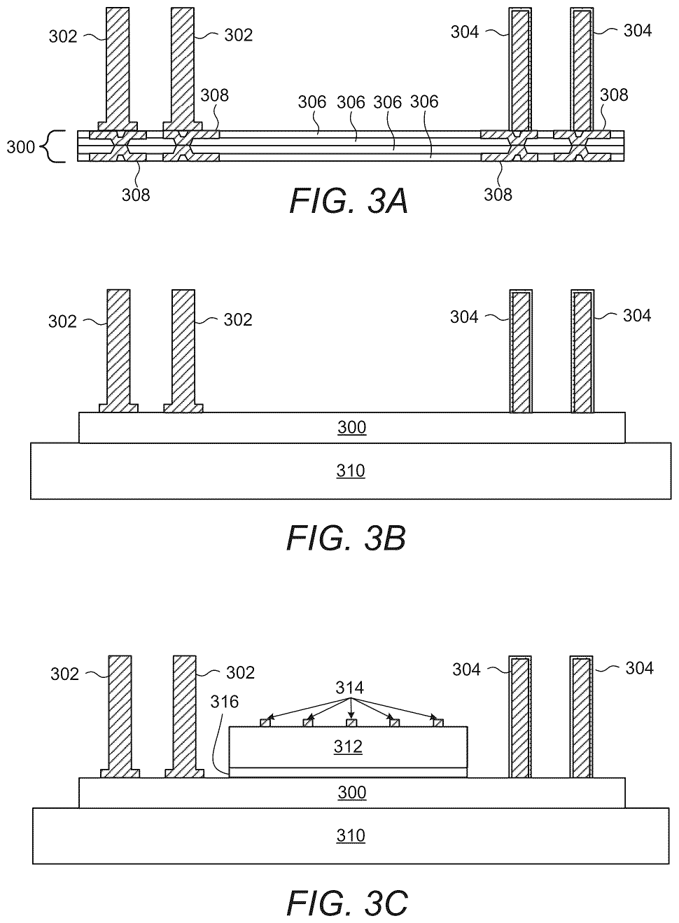

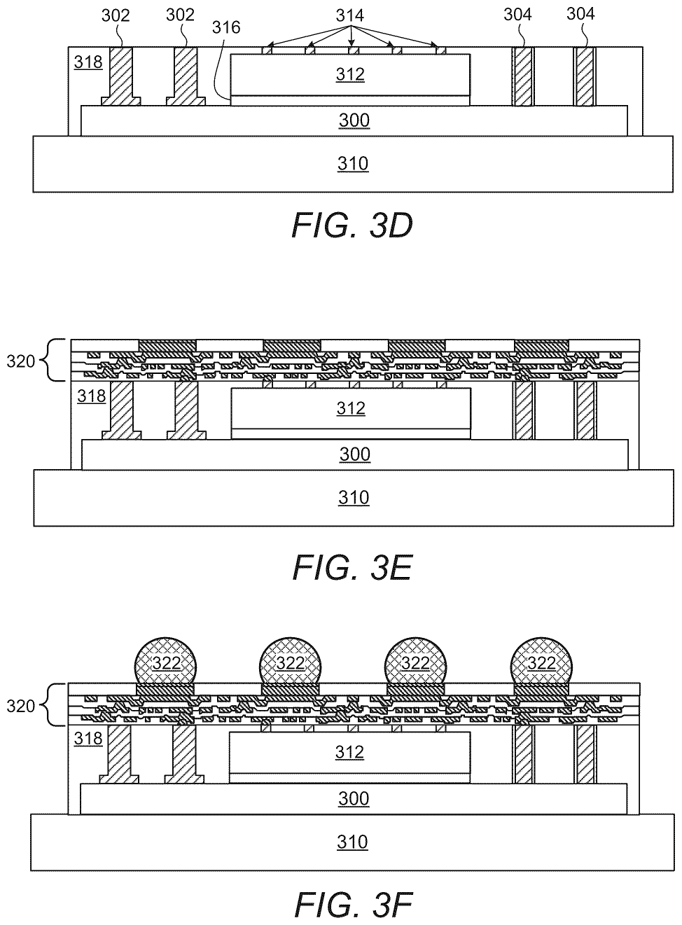

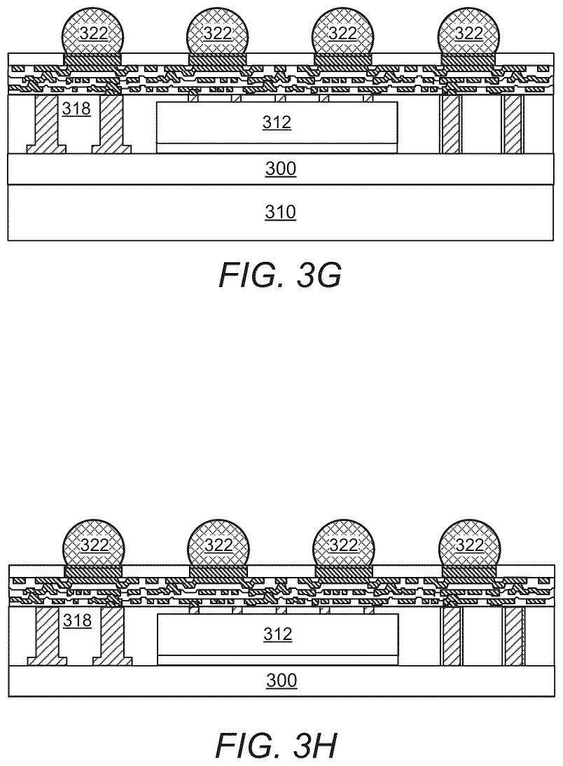

FIG. 3A through FIG. 3H illustrate portions of a process for fabricating a die-first metallization structure and substrate interposer hybrid package, according to aspects of the disclosure. Rather than having to fabricate a top-side RDL interposer 104 to which a DAF 112 and die 102 are attached, the process starts in FIG. 3A, with a substrate interposer 300, to which vertical conductors, e.g., either wire bonds 302 or copper pins 304, have been attached. In some aspects, the substrate interposer 300 was singulated (i.e., separated into an individual item or component from a group that was originally part of a unit piece) either before or after the vertical conductors were attached. In some aspects, the substrate interposer 300 comprises a printed circuit board (PCB) with one or more layers and with one or more layers of conductors. In the example shown in FIG. 3A, the substrate interposer 300 comprises multiple layers 306 and various metal routing structures 308, which will be omitted from later figures for clarity. The metal routing structures 308 at the bottom of the substrate interposer 300 will eventually become the top metal contacts of the finished apparatus, and are thus collectively referred to hereinafter as the “top contacts.”

FIG. 3B shows the result after the substrate interposer 300 is attached to a carrier 310 in a “pins up” position, i.e., with the vertical conductors facing away from the carrier 310 and the “top contacts” facing the carrier 310. In some aspects, the carrier 310 comprises an RDL carrier. In some aspects, more than one substrate interposer 300 may be attached to the same carrier 310; the following process steps will be performed for each substrate interposer 300.

FIG. 3C shows the result after the attachment of a die 312 to the substrate interposer 300. The die 312 has die contacts 314, and the die 312 is attached to the substrate interposer 300 in a “contact side up” position, i.e., with the die contacts 314 facing away from the substrate interposer 300. In the example shown in FIG. 3C, the die 312 is attached to the substrate interposer 300 using a DAF 316, but other attachment methods may be used. Although the example illustrated in FIGS. 3A-3H show a single die 312, in other aspects more than one die may be attached to each substrate interposer 300.

FIG. 3D shows the result after a molding step in which the substrate interposer 300, the die 312, DAF 316, and vertical conductors have been encased within a molding compound 318, which secures them into place together. The over-molding is then ground to expose the die contacts 314 and the vertical conductors.

FIG. 3E shows the result after build-up of a metallization structure 320 that makes electrical contact with the die contacts 314 and the vertical conductors. In some aspects, the metallization structure 320 may comprise RDL. FIG. 3F shows the result after placement of ball contacts 322. FIG. 3G shows the result after singulation. FIG. 3H shows the result after removal of the carrier 310, forming the finished hybrid package.

The advantages of the fabrication method described in FIGS. 3A-3H include, but are not limited to, faster processing time, because the substrate interposer 300 may be fabricated in advance or provided as a pre-made structure by another vendor, and lower cost, because substrate structures are generally less expensive than RDL structures. The compact routing enabled by the metallization structure 320 is typically not really needed for providing signal routing to a memory or other device that is piggybacked on top of the finished hybrid package.

It will be appreciated that the foregoing fabrication process was provided merely as general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

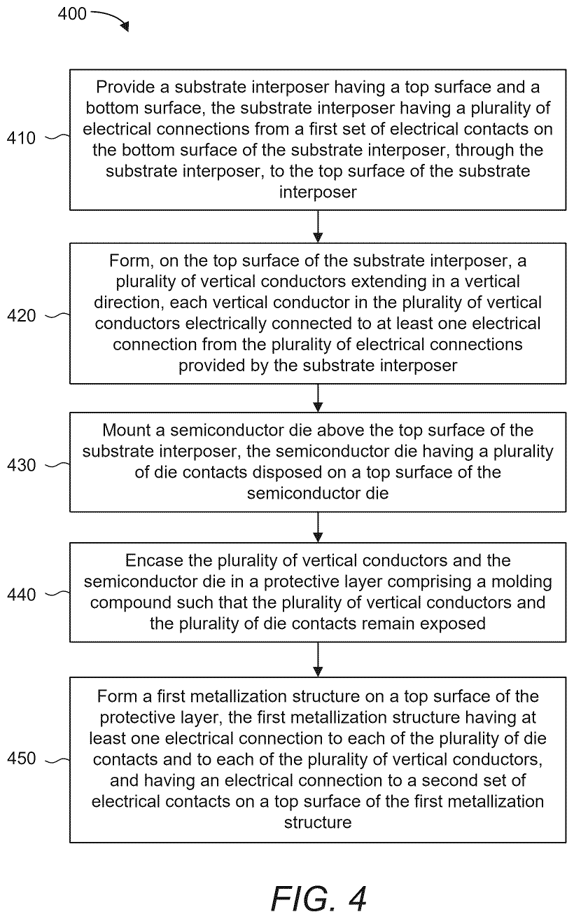

FIG. 4 is a flowchart of an example process 400 associated with die-first metallization structure and substrate interposer hybrid package, according to aspects of the disclosure. As shown in FIG. 4, process 400 may include, at block 410, providing a substrate interposer having a top surface and a bottom surface, the substrate interposer having a plurality of electrical connections from a first set of electrical contacts on the bottom surface of the substrate interposer, through the substrate interposer, to the top surface of the substrate interposer.

As further shown in FIG. 4, process 400 may include, at block 420, forming, on the top surface of the substrate interposer, a plurality of vertical conductors extending in a vertical direction, each vertical conductor in the plurality of vertical conductors electrically connected to at least one electrical connection from the plurality of electrical connections provided by the substrate interposer.

As further shown in FIG. 4, process 400 may include, at block 430, mounting a semiconductor die above the top surface of the substrate interposer, the semiconductor die having a plurality of die contacts disposed on a top surface of the semiconductor die.

As further shown in FIG. 4, process 400 may include, at block 440, encasing the plurality of vertical conductors and the semiconductor die in a protective layer comprising a molding compound such that the plurality of vertical conductors and the plurality of die contacts remain exposed.

As further shown in FIG. 4, process 400 may include, at block 450, forming a first metallization structure on a top surface of the protective layer, the first metallization structure having at least one electrical connection to each of the plurality of die contacts and to each of the plurality of vertical conductors, and having an electrical connection to a second set of electrical contacts on a top surface of the first metallization structure.

In some aspects, providing the substrate interposer comprises providing one or more vertically stacked layers, each layer comprising a glass fiber core, a laminate core, an Ajinomoto build-up film core, or a prepreg core, and each layer comprising a conducting structure that forms a portion of the plurality of electrical connections within the substrate interposer.

In some aspects, process 400 includes providing a plurality of ball contacts mounted to the second set of electrical contacts on the top surface of the first metallization structure.

In some aspects, forming the first metallization structure comprises forming a redistribution layer (RDL) structure comprising one or more polyimide layers.

In some aspects, the process 400 results in at least one electrical connection between at one electrical contact of the first set of electrical contacts on the bottom surface of the substrate interposer and at least one electrical contact of the second set of electrical contacts on a top surface of the first metallization structure.

In some aspects, the process 400 results in at least one electrical connection between at one electrical contact of the first set of electrical contacts on the bottom surface of the substrate interposer and at least one die contact of the plurality of die contacts.

In some aspects, the process 400 results in at least one electrical connection between at one electrical contact of the second set of electrical contacts on a top surface of the first metallization structure and at least one die contact of the plurality of die contacts.

In some aspects, at least one vertical conductor of the plurality of vertical conductors comprises a wire bond or a copper pin.

In some aspects, a thickness of the substrate interposer is in a range from 50 μm to 150 μm.

In some aspects, a thickness of the first metallization structure is in a range from 5 μm to 40 μm.

Process 400 may include additional implementations, such as any single implementation or any combination of implementations described below and/or in connection with one or more other processes described elsewhere herein. Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

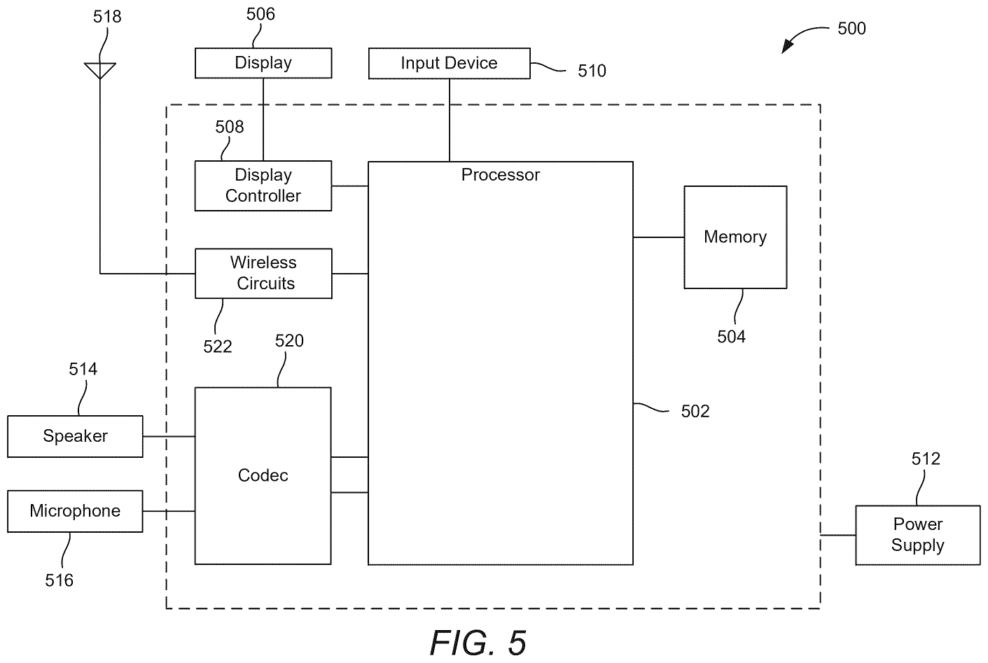

FIG. 5 illustrates a mobile device 500, according to aspects of the disclosure. In some aspects, the mobile device 500 may be implemented by including one or more IC devices manufactured based on the examples described in this disclosure.

In some aspects, mobile device 500 may be configured as a wireless communication device. As shown, mobile device 500 includes processor 502. Processor 502 may be communicatively coupled to memory 504 over a link, which may be a die-to-die or chip-to-chip link. Mobile device 500 also includes display 506 and display controller 508, with display controller 508 coupled to processor 502 and to display 506. The mobile device 500 may include input device 510 (e.g., physical, or virtual keyboard), power supply 512 (e.g., battery), speaker 514, microphone 516, and wireless antenna 518. In some aspects, the power supply 512 may directly or indirectly provide the supply voltage for operating some or all of the components of the mobile device 500.

In some aspects, FIG. 5 may include coder/decoder (CODEC) 520 (e.g., an audio and/or voice CODEC) coupled to processor 502; speaker 514 and microphone 516 coupled to CODEC 520; and wireless circuits 522 (which may include a modem, RF circuitry, filters, etc.) coupled to wireless antenna 518 and to processor 502.

In some aspects, one or more of processor 502, display controller 508, memory 504, CODEC 520, and wireless circuits 522 may include one or more IC devices including semiconductor structures manufactured according to the examples described in this disclosure.

It should be noted that although FIG. 5 depicts a mobile device 500, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

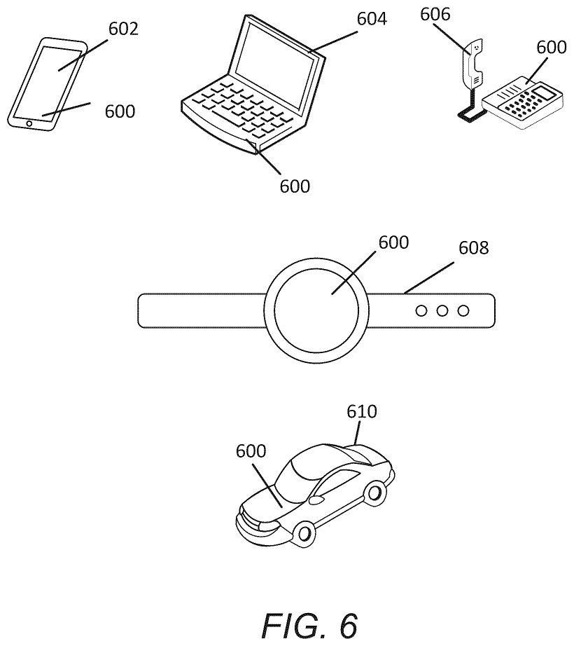

FIG. 6 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 602, a laptop computer device 604, a fixed location terminal device 606, a wearable device 608, or automotive vehicle 610 may include a semiconductor device 600 (e.g., apparatus 200) as described herein. The devices 602, 604, 606 and 608 and the vehicle 610 illustrated in FIG. 6 are merely exemplary. Other apparatuses or devices may also feature the semiconductor device 600 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An apparatus, comprising: a substrate interposer having a top surface and a bottom surface, the substrate interposer having a plurality of electrical connections from a first set of electrical contacts on the bottom surface of the substrate interposer, through the substrate interposer, to the top surface of the substrate interposer; a plurality of vertical conductors mounted to the top surface of the substrate interposer and extending in a vertical direction, each vertical conductor in the plurality of vertical conductors electrically connected to one electrical connection from the plurality of electrical connections provided by the substrate interposer; a semiconductor die, disposed above the top surface of the substrate interposer, and having a plurality of die contacts disposed on a top surface of the semiconductor die; and a first metallization structure, disposed above the semiconductor die and the plurality of vertical conductors, having at least one electrical connection to each of the plurality of die contacts and to each of the plurality of vertical conductors, and providing an electrical connection to a second set of electrical contacts on a top surface of the first metallization structure, wherein the semiconductor die and the plurality of vertical conductors are contained within a layer, disposed between the top surface of the substrate interposer and a bottom surface of the first metallization structure, comprising a molding compound.

Clause 2. The apparatus of clause 1, wherein the substrate interposer comprises one or more vertically stacked layers, each layer comprising a glass fiber core, a laminate core, an Ajinomoto build-up film core, or a prepreg core, and each layer comprising a conducting structure that forms a portion of the plurality of electrical connections within the substrate interposer.

Clause 3. The apparatus of any of clauses 1 to 2, further comprising a plurality of ball contacts mounted to the second set of electrical contacts on the top surface of the first metallization structure.

Clause 4. The apparatus of any of clauses 1 to 3, wherein the first metallization structure comprises a redistribution layer (RDL) structure comprising one or more polyimide layers.

Clause 5. The apparatus of any of clauses 1 to 4, comprising at least one electrical connection between at one electrical contact of the first set of electrical contacts on the bottom surface of the substrate interposer and at least one electrical contact of the second set of electrical contacts on a top surface of the first metallization structure.

Clause 6. The apparatus of any of clauses 1 to 5, comprising at least one electrical connection between at one electrical contact of the first set of electrical contacts on the bottom surface of the substrate interposer and at least one die contact of the plurality of die contacts.

Clause 7. The apparatus of any of clauses 1 to 6, comprising at least one electrical connection between at one electrical contact of the second set of electrical contacts on a top surface of the first metallization structure and at least one die contact of the plurality of die contacts.

Clause 8. The apparatus of any of clauses 1 to 7, wherein at least one vertical conductor of the plurality of vertical conductors comprises a wire bond or a copper pin.

Clause 9. The apparatus of any of clauses 1 to 8, wherein a thickness of the substrate interposer is in a range from 50 μm to 150 μm.

Clause 10. The apparatus of any of clauses 1 to 9, wherein a thickness of the first metallization structure is in a range from 5 μm to 40 μm.

Clause 11. A method for fabricating an apparatus, the method comprising: providing a substrate interposer having a top surface and a bottom surface, the substrate interposer having a plurality of electrical connections from a first set of electrical contacts on the bottom surface of the substrate interposer, through the substrate interposer, to the top surface of the substrate interposer; forming, on the top surface of the substrate interposer, a plurality of vertical conductors extending in a vertical direction, each vertical conductor in the plurality of vertical conductors electrically connected to at least one electrical connection from the plurality of electrical connections provided by the substrate interposer; mounting a semiconductor die above the top surface of the substrate interposer, the semiconductor die having a plurality of die contacts disposed on a top surface of the semiconductor die; encasing the plurality of vertical conductors and the semiconductor die in a protective layer comprising a molding compound such that the plurality of vertical conductors and the plurality of die contacts remain exposed; and forming a first metallization structure on a top surface of the protective layer, the first metallization structure having at least one electrical connection to each of the plurality of die contacts and to each of the plurality of vertical conductors, and having an electrical connection to a second set of electrical contacts on a top surface of the first metallization structure.

Clause 12. The method of clause 11, wherein providing the substrate interposer comprises providing one or more vertically stacked layers, each layer comprising a glass fiber core, a laminate core, an Ajinomoto build-up film core, or a prepreg core, and each layer comprising a conducting structure that forms a portion of the plurality of electrical connections within the substrate interposer.

Clause 13. The method of any of clauses 11 to 12, further comprising providing a plurality of ball contacts mounted to the second set of electrical contacts on the top surface of the first metallization structure.

Clause 14. The method of any of clauses 11 to 13, wherein forming the first metallization structure comprises forming a redistribution layer (RDL) structure comprising one or more polyimide layers.

Clause 15. The method of any of clauses 11 to 14, resulting in at least one electrical connection between at one electrical contact of the first set of electrical contacts on the bottom surface of the substrate interposer and at least one electrical contact of the second set of electrical contacts on a top surface of the first metallization structure.

Clause 16. The method of any of clauses 11 to 15, resulting in at least one electrical connection between at one electrical contact of the first set of electrical contacts on the bottom surface of the substrate interposer and at least one die contact of the plurality of die contacts.

Clause 17. The method of any of clauses 11 to 16, resulting in at least one electrical connection between at one electrical contact of the second set of electrical contacts on a top surface of the first metallization structure and at least one die contact of the plurality of die contacts.

Clause 18. The method of any of clauses 11 to 17, wherein at least one vertical conductor of the plurality of vertical conductors comprises a wire bond or a copper pin.

Clause 19. The method of any of clauses 11 to 18, wherein a thickness of the substrate interposer is in a range from 50 μm to 150 μm.

Clause 20. The method of any of clauses 11 to 19, wherein a thickness of the first metallization structure is in a range from 5 μm to 40 μm.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An apparatus, comprising:
a substrate interposer having a top surface and a bottom surface, the substrate interposer having a plurality of electrical connections from a first set of electrical contacts on the bottom surface of the substrate interposer, through the substrate interposer, to the top surface of the substrate interposer;
a plurality of vertical conductors mounted to the top surface of the substrate interposer and extending in a vertical direction, each vertical conductor in the plurality of vertical conductors electrically connected to one electrical connection from the plurality of electrical connections provided by the substrate interposer;
a semiconductor die, disposed above the top surface of the substrate interposer, and having a plurality of die contacts disposed on a top surface of the semiconductor die; and
a first metallization structure, disposed above the semiconductor die and the plurality of vertical conductors, having at least one electrical connection to each of the plurality of die contacts and to each of the plurality of vertical conductors, and providing an electrical connection to a second set of electrical contacts on a top surface of the first metallization structure,
wherein the semiconductor die and the plurality of vertical conductors are contained within a layer, disposed between the top surface of the substrate interposer and a bottom surface of the first metallization structure, comprising a molding compound.

2. The apparatus of claim 1, wherein the substrate interposer comprises one or more vertically stacked layers, each layer comprising a glass fiber core, a laminate core, an Ajinomoto build-up film core, or a prepreg core, and each layer comprising a conducting structure that forms a portion of the plurality of electrical connections within the substrate interposer.

3. The apparatus of claim 1, further comprising a plurality of ball contacts mounted to the second set of electrical contacts on the top surface of the first metallization structure.

4. The apparatus of claim 1, wherein the first metallization structure comprises a redistribution layer (RDL) structure comprising one or more polyimide layers.

5. The apparatus of claim 1, comprising at least one electrical connection between at one electrical contact of the first set of electrical contacts on the bottom surface of the substrate interposer and at least one electrical contact of the second set of electrical contacts on a top surface of the first metallization structure.

6. The apparatus of claim 1, comprising at least one electrical connection between at one electrical contact of the first set of electrical contacts on the bottom surface of the substrate interposer and at least one die contact of the plurality of die contacts.

7. The apparatus of claim 1, comprising at least one electrical connection between at one electrical contact of the second set of electrical contacts on a top surface of the first metallization structure and at least one die contact of the plurality of die contacts.

8. The apparatus of claim 1, wherein at least one vertical conductor of the plurality of vertical conductors comprises a wire bond or a copper pin.

9. The apparatus of claim 1, wherein a thickness of the substrate interposer is in a range from 50 μm to 150 μm.

10. The apparatus of claim 1, wherein a thickness of the first metallization structure is in a range from 5 μm to 40 μm.

11. A method for fabricating an apparatus, the method comprising:
providing a substrate interposer having a top surface and a bottom surface, the substrate interposer having a plurality of electrical connections from a first set of electrical contacts on the bottom surface of the substrate interposer, through the substrate interposer, to the top surface of the substrate interposer;
forming, on the top surface of the substrate interposer, a plurality of vertical conductors extending in a vertical direction, each vertical conductor in the plurality of vertical conductors electrically connected to at least one electrical connection from the plurality of electrical connections provided by the substrate interposer;
mounting a semiconductor die above the top surface of the substrate interposer, the semiconductor die having a plurality of die contacts disposed on a top surface of the semiconductor die;
encasing the plurality of vertical conductors and the semiconductor die in a protective layer comprising a molding compound such that the plurality of vertical conductors and the plurality of die contacts remain exposed; and
forming a first metallization structure on a top surface of the protective layer, the first metallization structure having at least one electrical connection to each of the plurality of die contacts and to each of the plurality of vertical conductors, and having an electrical connection to a second set of electrical contacts on a top surface of the first metallization structure.

12. The method of claim 11, wherein providing the substrate interposer comprises providing one or more vertically stacked layers, each layer comprising a glass fiber core, a laminate core, an Ajinomoto build-up film core, or a prepreg core, and each layer comprising a conducting structure that forms a portion of the plurality of electrical connections within the substrate interposer.

13. The method of claim 11, further comprising providing a plurality of ball contacts mounted to the second set of electrical contacts on the top surface of the first metallization structure.

14. The method of claim 11, wherein forming the first metallization structure comprises forming a redistribution layer (RDL) structure comprising one or more polyimide layers.

15. The method of claim 11, resulting in at least one electrical connection between at one electrical contact of the first set of electrical contacts on the bottom surface of the substrate interposer and at least one electrical contact of the second set of electrical contacts on a top surface of the first metallization structure.

16. The method of claim 11, resulting in at least one electrical connection between at one electrical contact of the first set of electrical contacts on the bottom surface of the substrate interposer and at least one die contact of the plurality of die contacts.

17. The method of claim 11, resulting in at least one electrical connection between at one electrical contact of the second set of electrical contacts on a top surface of the first metallization structure and at least one die contact of the plurality of die contacts.

18. The method of claim 11, wherein at least one vertical conductor of the plurality of vertical conductors comprises a wire bond or a copper pin.

19. The method of claim 11, wherein a thickness of the substrate interposer is in a range from 50 μm to 150 μm.

20. The method of claim 11, wherein a thickness of the first metallization structure is in a range from 5 μm to 40 μm.
